(19) United States
(12) Patent Application Publication
(10) Pub. No.: US 2004/0038438 A1
(43) Pub. Date: Feb. 26, 2004

(54) Method for reducing surface roughness of polysilicon films for liquid crystal displays

(75) Inventors: Chu-Jung Shih, Miao-Li Country (TW); Yaw-Ming Tsai, Miao-Li Country (TW)

Correspondence Address: Finngan, Henderson, Farabow,, Garrett & Dunner, L.L.P., 1300 I. Street, N.W., Washington, DC, 20005-3315, US

(73) Assignee: Toppoly Optoelectronics Corp.

(21) Appl. No.: 10/226,110

(22) Filed: Aug. 23, 2002

(51) Int. Cl. H01L 21/00; H01L 21/84

(52) U.S. Cl. 438/30; 438/166

(57) ABSTRACT

A method of silicon crystallization that includes providing an insulated substrate, depositing a layer of amorphous silicon over the substrate, crystallizing the layer of amorphous silicon in an oxygen environment for a reduced surface roughness on the layer of crystallized silicon, and oxidizing the layer of amorphous silicon simultaneously with crystallizing the layer of amorphous silicon to form a layer of gate insulator.

### DESCRIPTION OF THE INVENTION

1. Field of the Invention

The invention pertains in general to a method for manufacturing a polysilicon semiconductor layer in a liquid crystal display and, more particularly, to a method for manufacturing a polysilicon semiconductor layer with reduced surface roughness.

2. Background of the Invention

In the development of thin film transistor (“TFT”) liquid crystal display (“LCD”) technology, polycrystalline silicon, or polysilicon, has become a semiconductor layer of choice over amorphous silicon. In the manufacturing process, a layer of amorphous silicon is first deposited over an insulating substrate. The layer of amorphous silicon may be crystallized through a number of conventional methods, including excimer laser annealing (“ELA”) at a low temperature, solild phase crystallization (“SPC”) at a high temperature, continuous grain growth (“CGG”), metal induced crystallization (“MIC”), metal induced lateral crystallization (“MILC”), and sequential lateral solidification (“SLS”). These methods are performed in an oxygen-free environment.

An important consideration in the crystallization process is the grain size of the polycrystalline. If the grain size is too small, the polysilicon layer will exhibit low electron mobility and high resistance, each of which may adversely affect the electrical characteristics of the TFT LCD. Specifically, low electron mobility and high resistance may prevent pixel capacitors from being sufficiently charged, which may prevent display contrast from being accurately displayed, or cause errors in the operation of periphery driver circuits.

However, a polysilicon layer having a large grain size exhibits a rough surface, and the surface roughness increases as the grain size increases. In the TFT LCD manufacturing process, a gate insulator layer is formed over the polysilicon layer. The gate insulator layer generally is an oxide layer (SiO₂) grown over the polysilicon layer. As a result, the roughness of the polysilicon surface will determine the characteristics of the gate insulator layer. In addition, if the surface is too rough, a concentration of electrical field is created at the peak of the ridges on the polysilicon surface, which gives rise to leakage current. A leakage current in a pixel will adversely change the threshold voltage of the LCD pixels.

### SUMMARY OF THE INVENTION

In accordance with the invention, there is provided a method for manufacturing a liquid crystal display that includes providing a substrate, providing a layer of insulating material over the substrate, depositing a layer of amorphous silicon over the layer of insulating material, and crystallizing the layer of amorphous silicon in an oxygen environment for a reduced surface roughness on the layer of crystallized silicon.

In one aspect, the step of crystallizing the layer of amorphous silicon is performed with one of ashing, ozone, excimer ultraviolet light, or rapid thermal processing.

Also in accordance with the invention, there is provided a method of silicon crystallization that includes providing an insulated substrate, depositing a layer of amorphous silicon over the substrate, crystallizing the layer of amorphous silicon in an oxygen environment for a reduced surface roughness on the layer of crystallized silicon, and oxidizing the layer of amorphous silicon simultaneously with the crystallization of the layer of amorphous silicon to form a layer of gate insulator.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawing, which is incorporated in and constitutes a part of this specification, illustrates one embodiment of the invention and together with the description, serves to explain the principles of the invention.

### BRIEF DESCRIPTION OF THE DRAWINGS

FIG. 1 is a cross-sectional view of the manufacturing process consistent with the present invention.

### DESCRIPTION OF THE EMBODIMENTS

Reference will now be made in detail to the present embodiments of the invention, an example of which is illustrated in the accompanying drawing. Wherever possible, the same reference numbers will be used throughout the drawing to refer to the same or like parts.

Generally, during the crystallization process of an amorphous silicon layer, polysilicon dislocation is one of the main causes for the formation of a rough surface on a polysilicon layer. Dislocation of polysilicon crystalline usually occurs at the grain boundary. In addition, the crystallization process around the location where there is polysilicon dislocation is worse than other locations, resulting in a high concentration of dangling bonds. However, the dangling bonds are more conducive to the oxidation process, creating silicon oxides having a higher density compared to the silicon oxides produced elsewhere. Therefore, the present invention provides a method for silicon crystallization and producing or increasing the thickness of the silicon oxide formed on the polysilicon layer surface. The insulating layer thus formed has a high density of silicon oxides to prevent current leakage. At the same time, the present invention provides a method for providing a polysilicon surface with reduced surface roughness through the oxidation process. The present invention additionally provides an additional step of further reducing the surface roughness of the polysilicon layer.

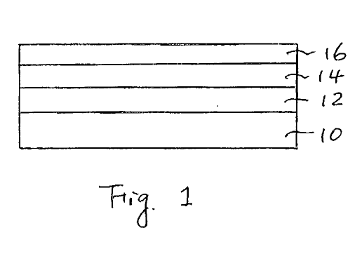

FIG. 1 is a cross-sectional view of the manufacturing process consistent with the present invention. Referring to FIG. 1, a substrate 10 is provided and defined. A first layer of insulating material 12 may be provided over the substrate 10. A silicon layer 14 is formed over the insulating material 12. Specifically, a layer of amorphous silicon 14 is deposited over the insulating material 12. The layer of amorphous silicon 14 may be deposited with any conventional deposition method.

The layer of amorphous silicon 14 is then crystallized. At the same time, a layer of silicon oxide 16, or gate insulator, is formed over the silicon layer 14. The crystallization process is performed in an oxygen environment to induce simultaneous oxidation on the surface of the silicon layer 14 to reduce surface roughness of the silicon layer 14. The crystallization may be performed with ashing, ozone (O₃), excimer ultraviolet light (“EUV”), or rapid thermal processing (“RTP”), or in an oven or hot plate at an elevated temperature. During the crystallization process, the gate insulator 16 is first formed as a native oxide. The thickness of the gate insulator 16 may be increased and controlled through the duration of the crystallization process.

The surface roughness of the silicon layer 14 may be further reduced by etching back the gate insulator 16 with buffer hydrogen-fluoride (BHF), diluted HF (DHF), or dry etch. The gate insulator 16 may be etched back partially or completely. If the gate insulator 16 is completely etched back, an additional oxidation step will be performed to form a gate insulator over the silicon layer 14.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for manufacturing a liquid crystal display, comprising:
providing a substrate;
providing a layer of insulating material over the substrate;
depositing a layer of amorphous silicon over the layer of insulating material; and
crystallizing the layer of amorphous silicon in an oxygen environment for a reduced surface roughness on the layer of crystallized silicon.

2. The method as claimed in claim 1, wherein the step of crystallizing the layer of amorphous silicon includes simultaneously oxidizing the layer of amorphous silicon to form a layer of gate insulator.

3. The method as claimed in claim 2, wherein the layer of gate insulator comprises silicon oxide.

4. The method as claimed in claim 2, wherein a thickness of the gate oxide is controlled through a duration of crystallizing the layer of amorphous silicon.

5. The method as claimed in claim 1, wherein the step of crystallizing the layer of amorphous silicon is performed with one of ashing, ozone, excimer ultraviolet light, or rapid thermal processing.

6. The method as claimed in claim 1, wherein the step of crystallizing is performed in an oven or hot plate at an elevated temperature.

7. The method as claimed in claim 2, further comprising etching back the layer of gate insulator.

8. The method as claimed in claim 7, wherein the step of etching back is performed with one of buffer hydrogen-fluoride, diluted hydrogen-fluoride, or dry etch.

9. A method of silicon crystallization, comprising:
providing an insulated substrate;
depositing a layer of amorphous silicon over the substrate;
crystallizing the layer of amorphous silicon in an oxygen environment for a reduced surface roughness on the layer of crystallized silicon; and
oxidizing the layer of amorphous silicon simultaneously with the crystallization of the layer of amorphous silicon to form a layer of gate insulator.

10. The method as claimed in claim 9, wherein the layer of gate insulator comprises silicon oxide.

11. The method as claimed in claim 9, wherein a thickness of the gate oxide is controlled through a duration of crystallizing the layer of amorphous silicon.

12. The method as claimed in claim 9, wherein the step of crystallizing the layer of amorphous silicon is performed with one of ashing, ozone, excimer ultraviolet light, or rapid thermal processing.

13. The method as claimed in claim 9, wherein the step of crystallizing is performed in an oven or hot plate at an elevated temperature.

14. The method as claimed in claim 9, further comprising etching back the layer of gate insulator.

15. The method as claimed in claim 14, wherein the step of etching back is performed with one of buffer hydrogen-fluoride, diluted hydrogen-fluoride, or dry etch.
